(19) United States
(12) Patent Application Publication
(10) Pub. No.: US 2005/0046482 A1
(43) Pub. Date: Mar. 3, 2005

(54) Receiver circuit

(76) Inventor: Karl Schrodinger, Berlin (DE)

Correspondence Address: LERNER AND GREENBERG, PA, P O BOX 2480, HOLLYWOOD, FL, 33022-2480, US

(21) Appl. No.: 10/649,409

(22) Filed: Aug. 27, 2003

(51) Int. Cl. H03F 3/08

(52) U.S. Cl. 330/308

(57) ABSTRACT

The invention is based on the object of specifying a receiver circuit which can be used in particularly universal fashion.

This object is achieved according to the invention by means of a receiver circuit (10) having an optical reception device (20) and having an amplifier (30) connected to the reception device (20), the amplifier (30) having at least one control terminal (S30), by means of which the gain (V) of the amplifier (30) can be changed over at least between two gain values at the user end.

### TECHNICAL FIELD

The invention relates to a receiver circuit having an optical reception device and having an amplifier connected downstream of the optical reception device. Light incident on the optical reception device—for example light from an optical waveguide of an optical data transmission system—is detected by the optical reception device with formation of an electrical signal (e.g. a photocurrent); the electrical signal is subsequently amplified by the amplifier connected downstream.

An optical receiver circuit having an optical reception device and having an amplifier connected downstream is described for example in the article “High Gain Transimpedance Amplifier in InP-Based HBT Technology for the Receiver in 40-Gb/s Optical-Fiber TDM Links” (Jens Müllrich, Herbert Thurner, Ernst Müllner, Joseph F. Jensen, Senior Member, IEEE, William E. Stanchina, Member, IEEE, M. Kardos, and Hans-Martin Rein, Senior Member, IEEE—IEEE Journal of Solid State Circuits, vol. 35, No. 9, September 2000, pages 1260 to 1265). In the case of this receiver circuit, at the input end there is a differentially operated transimpedance amplifier—that is to say a differential amplifier—connected by one input to a photodiode as reception device. The other input of the differentially operated transimpedance amplifier is connected to a DC amplifier which feeds a “correction current” into the differential amplifier for the purpose of offset correction of the photocurrent of the photodiode. The magnitude of this “correction current” that is fed in amounts to half the current swing of the photodiode during operation.

### SUMMARY OF THE INVENTION

The invention is based on the object of specifying a receiver circuit which can be used in particularly universal fashion.

This object is achieved according to the invention by means of an optical receiver circuit having the features in accordance with patent claim 1. Advantageous refinements of the invention are specified in subclaims.

Accordingly, the invention provides a receiver circuit having an optical reception device and an amplifier connected downstream. According to the invention, the amplifier has at least one control terminal, by means of which the gain of the amplifier can be changed over at least between two gain values at the user end.

One essential advantage of the receiver circuit according to the invention is to be seen in the fact that this receiver circuit enables an optimal optical sensitivity. This is because the invention's adjustability of the gain of the amplifier makes it possible to set the maximum gain of the amplifier depending on the prescribed bandwidth, or bandwidth to be achieved, of the receiver circuit. By way of example, on account of the approximately constant bandwidth (B)-gain (V) product (B*V=K; K results from the individual configuration of the receiver circuit), it is possible to set the maximum gain V and thus the maximum sensitivity of the receiver circuit by choosing
V=K/B.

The receiver circuit according to the invention can thus be used optimally for different data rates. Thus, on account of the gain that can be changed over, the receiver circuit according to the invention can be individually adapted for example to transmission rates of 1 Gbps (gigabit per second), 2 Gbps or 4 Gbps.

A further essential advantage of the receiver circuit according to the invention consists in its optimal noise behavior. By way of example, if a photodiode is used as reception device and a transimpedance amplifier is used as amplifier, then the current noise has a particularly relevant part to play in the amplifier. However, the current noise generally becomes lower toward higher gains of the amplifier, so that, when the optimum—that is to say maximum—gain is chosen, the current noise of the amplifier also decreases. However, with other types of amplifier, too, it generally holds true that the signal-to-noise ratio becomes better in the case of a higher gain. In summary, an optimum noise behavior can be achieved in the receiver circuit as a result of the user-end setting of the optimum gain value depending on the respective bandwidth requirement.

A photodiode is preferably used as the optical reception device since said photodiode can be produced simply and cost-effectively. Transimpedance amplifiers, for example, are particularly suitable as the amplifier.

The amplifier preferably has a feedback impedance, which influences the gain of the amplifier. The impedance of the feedback impedance can then be set externally at the user end by means of the at least one control terminal. In particular, the resistance of the feedback impedance should be able to be set at the user end by means of the at least one control terminal.

In order to be able to ensure the adjustability of the impedance of the feedback impedance in a particularly simple manner, one advantageous development of the receiver circuit proposes that the feedback impedance is formed by an impedance network with at least one switching device, which can be changed over at the user end by means of the at least one control terminal and which alters the impedance or the resistance of the impedance network in the case of a changeover.

The switching device is preferably formed by a switching transistor, in particular a MOS-FET transistor.

Another advantageous development of the receiver circuit proposes that the feedback impedance is formed by an impedance network with at least one variable impedance, the impedance of which can be set at the user end within a predetermined impedance range at least approximately linearly by means of the control terminal. The variable impedance may be formed for example by a transistor, in particular a MOS-FET transistor.

The receiver circuit is preferably packaged in a TO-46 package or in a corresponding plastic package (e.g. TSSOP10 or VQFN20).

The invention is furthermore based on the object of specifying a method for operating an optical receiver circuit in which an optimum noise behavior is achieved depending on the bandwidth requirements present in the concrete application.

This object is achieved according to the invention by means of a method in which a maximum gain value is prescribed for an amplifier of the receiver circuit in a manner dependent on a prescribed bandwidth of the receiver circuit and the gain value of the amplifier is set by means of a control terminal of the amplifier. The output signal of an optical reception device of the receiver circuit is then amplified by the amplifier with the set gain.

With regard to the advantages of the method according to the invention, reference is made to the above explanations concerning the receiver circuit according to the invention.

The gain value (V) of the amplifier may preferably be determined in accordance with
V=K/B,
where K specifies a maximum achievable bandwidth-gain product previously determined, for example by measurement, for the receiver circuit and B specifies the prescribed bandwidth.

In transimpedance amplifiers, the bandwidth is approximately proportional to the reciprocal of the feedback impedance, that is to say to 1/feedback impedance, since the gain is proportional to the feedback impedance. In this case, the gain is determined by the so-called transimpedance (=output voltage/input current).

### EXEMPLARY EMBODIMENTS

For elucidating the invention,

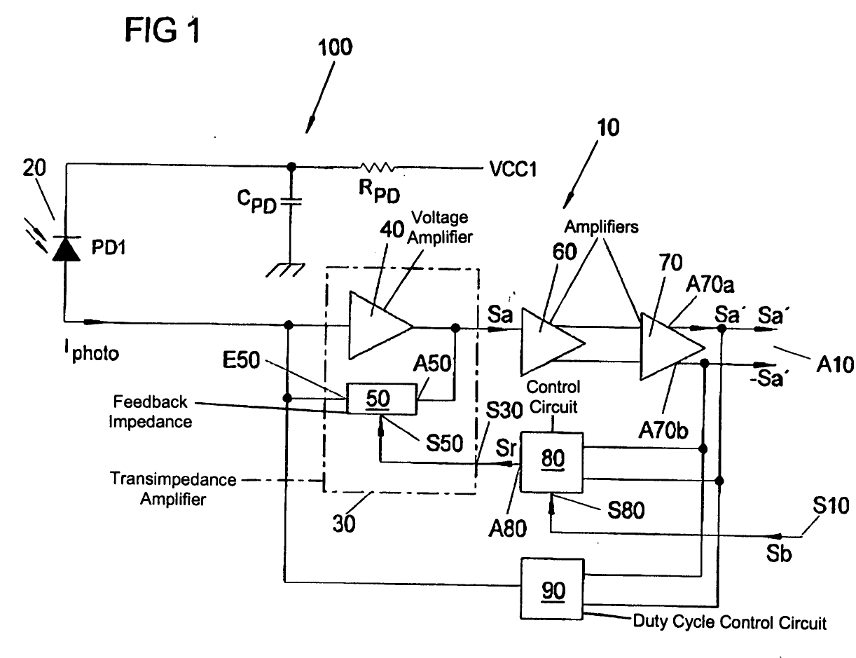

FIG. 1 shows a first exemplary embodiment of a receiver circuit according to the invention, which can also be used to carry out the method according to the invention,

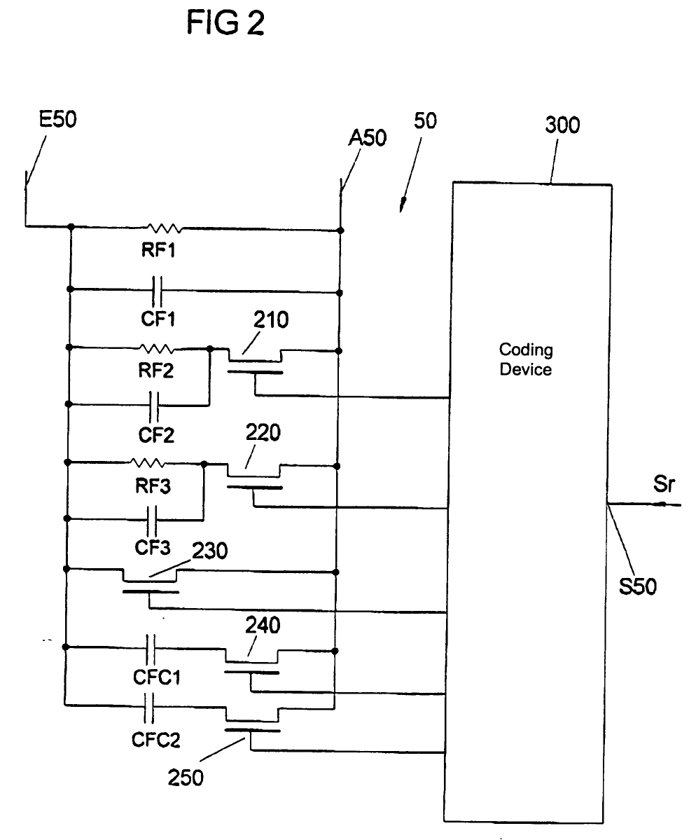

FIG. 2 shows an exemplary embodiment of a feedback impedance for the optical receiver circuit in accordance with FIG. 1, and

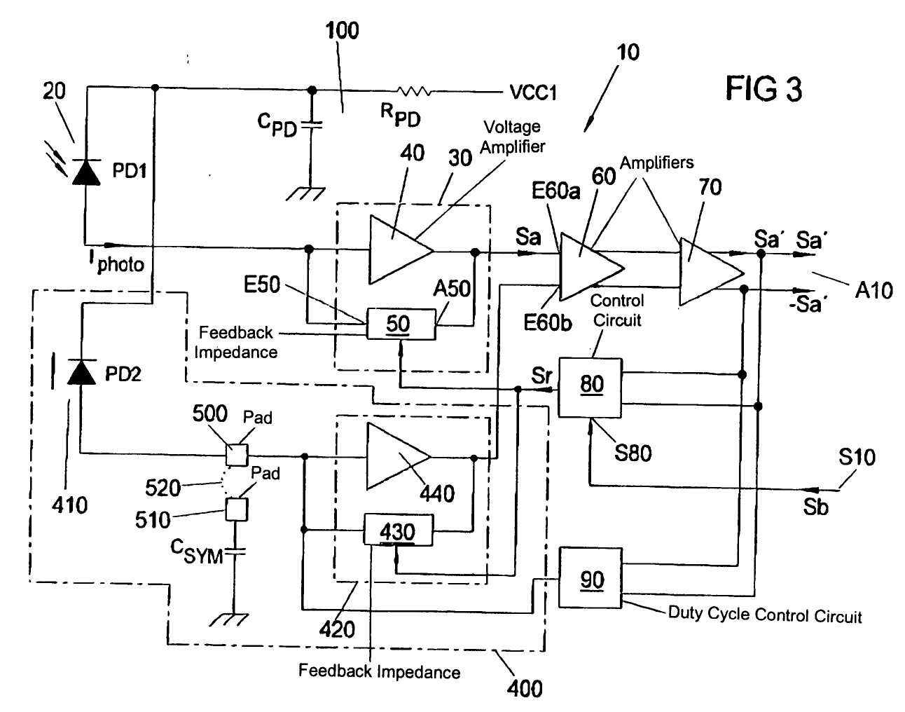

FIG. 3 shows a further exemplary embodiment of a receiver circuit according to the invention.

FIG. 1 reveals a receiver circuit 10 with a photodiode 20 as optical reception device. A transimpedance amplifier 30 is arranged downstream of the photodiode 20. The transimpedance amplifier 30 comprises a voltage amplifier 40, for example an operational amplifier, and a feedback impedance 50. The feedback impedance 50 is connected to the input end of the operational amplifier 40 by its terminal E50 and to the output end of the operational amplifier 40 by its terminal A50.

At the output end, the transimpedance amplifier 30 is additionally connected to a differential amplifier 60, which amplifies the output signal Sa of the transimpedance amplifier 30. Further amplification of the signal is effected by a further differential amplifier 70 arranged downstream of the first differential amplifier 60.

FIG. 1 furthermore reveals a control circuit 80, which, at the input end, is connected to the two outputs A70a and A70b of the differential amplifier 70. The control circuit 80 additionally has a control input S80, via which a user-end control signal Sb can be fed into the control circuit 80. The control input S80 thus forms a control terminal S10 of the receiver circuit 10.

By an output A80, the control circuit 80 is connected to a control terminal S30 of the transimpedance amplifier 30 and thus to a control input S50 of the feedback impedance 50. Via said control input S50, the control circuit 80 can define the impedance, in particular also the resistance, of the feedback impedance 50 by means of an impedance specification signal Sr formed from the user-end control signal Sb.

Furthermore, the optical receiver circuit is equipped with a DCC circuit 90 (DCC: Duty Cycle Control), which effects a control of the optical receiver circuit. The DCC circuit 90 or the duty cycle control formed by it (offset control) controls the sampling threshold for the downstream differential amplifiers, so that the signal is sampled at the 50% value of the amplitude and, as a result, no signal pulse distortions (duty cycle) are produced. This can be effected by feeding a current into a respective one of the preamplifiers (transimpedance amplifiers) or else by feeding in a voltage at the inputs of the differential amplifiers directly.

The photodiode 20 is connected via a low-pass filter 100 formed from a capacitor C_{PD} and a resistor R_{PD}, a supply voltage VCC1 being applied to said filter. The low-pass filter 100 serves to “filter out” possible interference signals on the supply voltage VCC.

The optical receiver circuit 10 in accordance with FIG. 1 is operated as follows:
when light is incident, a photocurrent Iₚₕₒₜₒ is generated by the photodiode 20 and fed into the transimpedance amplifier 30, where the photocurrent is amplified to form the output signal Sa. The electrical output signal Sa is amplified further by the two differential amplifiers 60 and 70 to form an amplified output signal Sa′ and passes to the output A10 of the optical receiver circuit 10; the output A10 of the optical receiver circuit 10 is thus formed by the two outputs A70a and A70b of the further differential amplifier 70.

The gain of the transimpedance amplifier 30 is set at the user end by means of the control signal Sb via the control terminal S80 of the control circuit 80 or via the control terminal S10 of the receiver circuit 10. For this purpose, the control signal Sb generated at the user end passes to the control circuit 80, which, with its impedance specification signal Sr, sets the resistance of the feedback impedance 50. This is because the magnitude of the resistance (|R|) of the feedback impedance 50 directly influences the gain of the transimpedance amplifier 30 because the following holds true:
Sa=|R|*Iₚₕₒₜₒ
thus, in the case of the arrangement in accordance with FIG. 1, the gain of the transimpedance amplifier 30 can be prescribed at the user end by means of the control signal Sb.

When prescribing an optimum gain value for the transimpedance amplifier 30, it is necessary to take account of the bandwidth B respectively required. In concrete terms, a very large gain is possible given a very small bandwidth, whereas only a very small gain can be achieved given a very large bandwidth. In concrete terms, this is due to the fact that, to a first approximation, the bandwidth-gain product (V*B) of the receiver circuit 10 is approximately constant and is prescribed by the individual configuration of the receiver circuit. The product V*B can be determined by measurement, for example.

Thus, if a specific bandwidth is prescribed or is at least to be achieved, then the maximum permissible gain can be derived from this at the user end. A corresponding gain value is then set by the control circuit 80 through the selection of the corresponding magnitude of the feedback impedance 50.

The desired gain can therefore be prescribed at the user end via the control input S80 and thus by means of the control signal Sb. As an alternative—given a corresponding configuration of the control circuit 80—a bandwidth to be achieved can also be communicated to the control circuit 80 at the user end by means of the control signal Sb, from which the maximum permissible gain V is then determined by the control circuit 80 in accordance with the mathematical relationship mentioned above and is communicated to the transimpedance amplifier 30 via the output A80 and the control terminal S50.

In connection with FIG. 1, the user-end control signal Sb was conducted to the transimpedance amplifier 30 via the control device 80. Instead of this, the user-end control signal Sb may also be applied directly to the control terminal S30 of the transimpedance amplifier 30.

Moreover, the transimpedance amplifier 30, the two differential amplifiers 60 and 70, the control circuit 80 and the DCC circuit 90 may also be regarded as one “amplifier unit” or as one “amplifier” whose control terminal for feeding in the user-end control signal Sb is formed by the terminal S80 of the control circuit 80.

FIG. 2 illustrates an exemplary embodiment of a feedback impedance 50 in accordance with FIG. 1. The feedback impedance is formed by an impedance network. The illustration reveals an ohmic resistor RF1, with which three capacitors CF1, CF2, CF3, CFC1 and CFC2 are connected in parallel. In addition, further ohmic resistors RF2 and RF3 are connected in parallel with the resistor RF1.

As can be discerned in FIG. 2, the resistor RF2 and the capacitor CF2 are connected in parallel and are connected to a switching transistor 210. If the switching transistor 210 is switched off, then the resistor RF2 and the capacitor CF2 play no part in the total impedance of the impedance network. By contrast, if the switching transistor 210 is switched on, then the resistors RF1 and RF2 form an ohmic parallel connection, with the result that the total resistance of the impedance network is reduced. The capacitor CF2 correspondingly increases the total capacitance of the impedance network since the capacitor CF2 is added to the capacitor CF1.

The resistor RF3 and the capacitor CF3 can be connected in parallel with the first resistor RF1 in a corresponding manner by means of a second switching transistor 220.

FIG. 2 furthermore reveals a MOS-FET transistor 230, which represents a linearly controllable resistor. Depending on the gate voltage applied to the MOS-FET transistor, a transistor resistor is produced which is connected in parallel with the first resistor RF1 and thus linearly reduces the total resistance of the impedance network. The resistance of the impedance network can be set in a continuously variable manner by application of the gate voltage.

Via a third switching transistor 240 and a fourth switching transistor 250, the capacitor CFC1 and the capacitor CFC2 can likewise be connected in parallel with the first resistor RF1, or else “disconnected”.

FIG. 2 furthermore reveals a coding device 300, the input E300 of which forms the control terminal S50 of the feedback impedance 50 in accordance with FIG. 1. At the output end, the coding device 300 is connected to the four switching transistors 210, 220, 240 and 250 and also to the linearly operating MOS-FET transistor 230.

The coding device 300 serves to recode the impedance specification signal Sr formed by the control circuit 80 in such a way that the feedback impedance 50 or the impedance network forms the desired impedance and the transimpedance amplifier 30 thus achieves the required gain.

The impedance network is driven as follows for the operation of the receiver circuit in accordance with FIG. 1:

The resistor RF1 serves for setting the largest gain and thus the smallest bandwidth of the transimpedance amplifier 30. In this operating mode—that is to say with the smallest bandwidth—the second resistor RF2 and the third resistor RF3 are disconnected by the two switching transistors 210 and 220. The capacitor CF1 serves for compensation against oscillation tendencies of the receiver circuit 10.

If a higher data rate is required, then the second resistor RF2 is connected in, by way of example; a lower transimpedance impedance is thus produced as a result of the two resistors RF1 and RF2 being connected in parallel, as a result of which the gain of the transimpedance amplifier 30 is reduced and the bandwidth is increased.

As a result of further connection—for example of the third resistor RF3—the resistance of the feedback impedance 50 and thus the gain of the transimpedance amplifier 30 can be reduced further, as a result of which the bandwidth is increased further. The compensation capacitors CF2 and CF3 that are necessary, if appropriate, for compensation against oscillation tendencies are additionally connected in at the same time as the two resistors RF2 and RF3 by the two switching transistors 210 and 220. In this case, the transistors 210, 220, 230, 240 and 250 are changed over by the control signal SV by means of the coding device 300.

The function of the MOS-FET transistor 230, which is likewise controlled by the coding device 300 and the control circuit 80, serves primarily for amplitude control. If the output power of the transimpedance amplifier rises increasingly, then the transistor 230 is driven linearly, so that the feedback impedance (transimpedance impedance) 50 of the transimpedance amplifier 30 is continuously decreased: overdriving of the transimpedance amplifier 30 can be prevented in this way. In order to be able to identify an increase in the output power of the transimpedance amplifier 30, the control circuit 80 in accordance with FIG. 1 is connected to the output signals Sa′ and −Sa′ of the further differential amplifier 70.

The additional capacitors CFC1 and CFC2 can be connected in with the associated switching transistors 240 and 250 in order to avoid oscillations; this may be necessary particularly when the feedback impedance 50 of the transimpedance amplifier 30 is decreased linearly on account of the MOS-FET transistor 230.

In summary, in the case of the exemplary embodiment in accordance with FIG. 2, the feedback impedance 50 is reduced by resistors and/or capacitors being connected in “parallel”. Instead of this or in addition, a changeover of the impedance of the feedback impedance 50 may also be achieved through a series circuit of connectable resistors and/or connectable capacitors.

The coding device 300 may be formed for example by an integrated circuit which correspondingly converts the impedance specification signal Sr in such a way that the transistors 210, 220, 230, 240 and 250 are driven in the manner explained above.

FIG. 3 illustrates a second exemplary embodiment of an optical receiver circuit 10 according to the invention. The optical receiver circuit in accordance with FIG. 3 differs from the receiver circuit in accordance with FIG. 1 by virtue of an additional receiver path 400 connected upstream of the differential amplifier 60. The additional receiver path 400 has a “dummy” photodiode 410, which is connected to the low-pass filter 100 and thus to the supply voltage VCC1. The “dummy” photodiode 410 is connected to a transimpedance amplifier 420, which, at the output end, is connected to a further input of the differential amplifier 60.

The function of the “dummy” photodiode 410 is to simulate the electrical behavior of the photodiode 10, to be precise for an “illumination-free case”. An “illumination-free case” is understood here to mean that the “dummy” photodiode 410 behaves to the greatest possible extent just like the photodiode 10 if no light to be detected impinges on the photodiode. In order to prevent light from being able to impinge on the “dummy” photodiode 410, the latter is correspondingly darkened, which is illustrated by a bar in FIG. 3.

One advantage of the receiver circuit in accordance with FIG. 3 is that it has a “fully differential” design or a quasi-symmetrical input-end circuitry of the differential amplifier 60. In this case, the fully differential design is based on the “dummy” photodiode 410 which simulates the electrical behavior of the photodiode 10 in the illumination-free case. The differential amplifier 60 is connected up symmetrically on account of the “dummy” photodiode 410, so that high-frequency interference is effectively suppressed. This is because high-frequency interference will occur simultaneously on account of the symmetrical input-end circuitry of the differential amplifier 60 at the two inputs E60a and E60b of the differential amplifier 60, so that the interference is suppressed to the greatest possible extent by virtue of the common-mode rejection that is customarily high in the case of the differential amplifier 60.

The optical receiver circuit in accordance with FIG. 3 is thus a development of the receiver circuit described in FIG. 1 which, although it has a differential amplifier at the input end, is connected up asymmetrically at the input end. Potential interference elements such as the bonding wire of the photodiode 10, the capacitance of the photodiode 10 and further capacitive construction elements—for example capacitances and inductances in the region of the photodiode 10—are unimportant in the arrangement in accordance with FIG. 3 since their influence or their interference signals are suppressed by the differential amplifier 60. This is based in concrete terms on the fact that the interference signals going back to the photodiode 10 are formed in a corresponding manner by the “dummy” photodiode 410 and thus pass “in common mode” to the differential amplifier 60 and are suppressed there.

In order to enable fully symmetrical operation of the optical receiver circuit in accordance with FIG. 3, at the output end the control circuit 90 is connected by its output A80 both to the feedback impedance 50 of the transimpedance amplifier 30 and to a feedback impedance 430 of the transimpedance amplifier 420, which likewise has an operational amplifier 440, so that the two feedback impedances 50 and 430 are driven in the same way.

The two transimpedance amplifiers 30 and 420 thus have the same gain behavior, so that “fully symmetrical” operation of the differential amplifier 60 is made possible because the receiver path formed by the photodiode 10 and the additional receiver path 400 formed by the “dummy” photodiode 410 are in parallel.

With regard to the remaining properties of the receiver circuit in accordance with FIG. 3, reference is made to the above explanations in connection with FIG. 1. By way of example, the impedance network in accordance with FIG. 2 may be used as feedback impedance 50 and as feedback impedance 430.

FIG. 3 furthermore reveals terminal pads 500 and 510, which can be connected to one another by means of a bonding wire 520. By means of such a bonding wire 520, the capacitor C_{SYM} can be connected to the further transimpedance amplifier 420. In this case, the capacitor C_{SYM} may replace the “dummy” photodiode 410 if such a photodiode 410 is not available. The capacitor C_{SYM} is then preferably dimensioned in such a way that it essentially corresponds to the capacitance of the “absent” dummy photodiode 410 or the capacitance of the useful diode 10.

List of Reference Symbols

10 Receiver circuit
20 Photodiode
30 Transimpedance amplifier
40 Operational amplifier
50 Feedback impedance (transimpedance impedance)
60 Differential amplifier
70 Further differential amplifier
80 Control circuit
90 DCC circuit
100 Low-pass filter
200/210 Switching transistor
220 Switching transistor
230 Linearly controllable MOS-FET transistor
240 Switching transistor
250 Switching transistor
300 Coding device
400 Additional receiver path
410 “Dummy” photodiode
420 Second transimpedance amplifier
500 Terminal pad
510 Terminal pad
520 Bonding wire
Sr Impedance specification signal
Sb User-end control signal

1-16. (canceled).

17. A receiver circuit, comprising:
an optical reception device; and
an amplifier connected to said reception device;
said amplifier having a gain; and
said amplifier including at least one control terminal for changing said gain of said amplifier between at least two gain values.

18. The receiver circuit according to claim 17, wherein said amplifier is a transimpedance amplifier.

19. The receiver circuit according to claim 17, wherein said amplifier has a feedback impedance for influencing said gain of said amplifier.

20. The receiver circuit according to claim 19, wherein said feedback impedance has an impedance value that is set by a signal at said control terminal.

21. The receiver circuit according to claim 20, wherein said feedback impedance has a resistance value that is set by a signal at said control terminal.

22. The receiver circuit according to claim 20, wherein:
said feedback impedance is formed by an impedance network with at least one switching device that is switched by said signal at said control terminal; and
said switching device alters said impedance of said feedback impedance when said switching device is switched.

23. The receiver circuit according to claim 22, wherein said switching device is formed by a switching transistor.

24. The receiver circuit according to claim 23, wherein said switching transistor is a MOS-FET transistor or a bipolar transistor.

25. The receiver circuit according to claim 19, wherein:
said feedback impedance is formed by an impedance network with at least one variable impedance that can be set at least approximately linearly within a predetermined impedance range by a signal at said control terminal.

26. The receiver circuit according to claim 25, wherein said variable impedance is formed by a transistor.

27. The receiver circuit according to claim 26, wherein said variable impedance is formed by a MOS-FET transistor or a bipolar transistor.

28. The receiver circuit according to claim 17, wherein said reception device is a photodiode.

29. The receiver circuit according to claim 17, further comprising:
a package for packaging said optical reception device (20) and said amplifier;
said package being a TO-46 package, a TSSOP10 package, or a VQFN20 package.

30. The receiver circuit according to claim 29, wherein said package has a terminal pin forming said control terminal.

31. A method for operating an optical receiver circuit, the method which comprises:
prescribing a gain value for an amplifier of the receiver circuit in dependence on a bandwidth prescribed for the receiver circuit;
setting the gain value of the amplifier at a control terminal of the amplifier; and
after setting the gain value of the amplifier, using the amplifier to amplify an output signal of an optical reception device.

32. The method according to claim 31, which further comprises:
determining the gain value in accordance with an equation:
V=K/B,
K specifying a maximum achievable bandwidth-gain product previously determined for the receiver circuit and B denoting the bandwidth prescribed for the receiver circuit.
